(19) United States
(12) Patent Application Publication
(10) Pub. No.: US 2026/0338861 A1
(43) Pub. Date: Oct. 29, 2026

(54) REGISTER WITH INTEGRATED ERROR DETECTION LOGIC

(71) Applicant: GlobalFoundries U.S. Inc., Malta, NY (US)

(72) Inventors: Siddharth Gupta, Uttar Pradesh (IN); Muthu Kumaran Nambi, Bangalore (IN); Sheikh Sabiq Chishti, Imphal (IN); Devesh Dwivedi, Bangalore (IN)

(21) Appl. No.: 19/186,872

(22) Filed: Apr. 23, 2025

(51) Int. Cl. G01R 31/3185

(52) U.S. Cl. CPC G01R 31/318525

(57) ABSTRACT

A structure includes a register with an array of flip-flops and integrated error detection logic. Each flip-flop is associated with one of multiple parity groups and any two adjacent flip-flops (in any direction) are associated with two different parity groups. This ensures that any flip-flops in the same parity group are separated by a minimum separation distance greater than the radius of a defined bit-flip occurrence region encircling a location of strike by an alpha particle or of generation of a secondary ion due to a neutron interaction. The parity groups can include even and odd parity groups. The integrated error detection logic includes: first logic circuits that generate group-specific error indicators for the parity groups; and a second logic circuit that generates a final error indicator for the register based on the group-specific error indicators. The final error indicator is indicative of any of multiple different types of errors.

### BACKGROUND

The present disclosure relates to registers and, more particularly, to embodiments of a structure including a register with integrated error detection logic.

In some applications (e.g., automotive applications) critical electronic components must operate in a fault-tolerant manner to prevent system failure and thereby prevent potentially hazardous operating conditions. Registers (also referred to herein as configuration registers) may store configuration data (e.g., operating bias, trim and speed settings or the like) to define the exact parameters required for such critical electronic components. Configuration data is typically stored in a register and static (i.e., it remains unchanged through the lifetime of the product). Thus, the timing vulnerability factor (TVF) is significantly high and it is likely that, at some point over the course of the lifetime of the product, one or more bits of the configuration data will be switched (e.g., due to radiation-induced soft errors). Unfortunately, if even one bit of the configuration data is corrupted, a critical electronic component may malfunction.

### SUMMARY

Disclosed herein are embodiments of a structure including a register with integrated error detections.

Some embodiments of the structure can include a register. The register can include an array of flip-flops. Each flip-flop in the array can be associated with one of multiple parity groups. Furthermore, any two adjacent flip-flops within the array can be associated with two different parity groups of the multiple parity groups. The structure can further include first logic circuits for the multiple parity groups, respectively. Each first logic circuit for a corresponding parity group can receive data from all flip-flops in that corresponding parity group and can output a corresponding group-specific error indicator. That is, the first logic circuits output group-specific error indicators for the multiple parity groups, respectively.

Other embodiments of the structure can include a register. The register can include an array of flip-flops. Each flip-flop in the array can be associated with one of multiple parity groups. The multiple parity groups include a combination of both even parity groups and odd parity groups. Furthermore, any two adjacent flip-flops within the array can be associated with two different parity groups of the multiple parity groups. The register can further include additional flip-flops, which store group-specific parity bits for the multiple parity groups, respectively. The structure can further include first logic circuits for the multiple parity groups, respectively. Each first logic circuit for a corresponding even parity group can be connected to receive data from all flip-flops in the corresponding even parity group plus a group-specific even parity bit stored in an additional flip-flop for the corresponding even parity group. Each first logic circuit for a corresponding odd parity group can be connected to receive data from all flip-flops in the corresponding odd parity group and an inverted group-specific odd parity bit stored in an additional flip-flop for the corresponding odd parity group. Each first logic circuit can output a corresponding group-specific error indicator. That is, the first logic circuits can output group-specific error indicators for the multiple parity groups, respectively.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram of an embodiment of a structure including a register with integrated error detection logic;

FIG. 2 is a schematic diagram of a D flip-flop that could be incorporated into the array of flip-flops in the structure of FIG. 1;

FIGS. 3A-3D are layout diagrams highlighting locations of flip-flops within an array but associated with different parity groups 0-3, respectively;

FIGS. 4A-4D are schematic diagrams of first logic circuits that could be incorporated into the structure of FIG. 1;

FIG. 5 is a schematic diagram of a second logic circuit that could be incorporated into the structure of FIG. 1; and

FIG. 6 is a schematic diagram illustrating another embodiment of a structure including a register with integrated error detection logic.

### DETAILED DESCRIPTION

As mentioned above, in some applications (e.g., automotive applications) critical electronic components must operate in a fault-tolerant manner to prevent system failure and thereby prevent potentially hazardous operating conditions. Registers (also referred to herein as configuration registers) may store configuration data (e.g., operating bias, trim and speed settings or the like) to define the exact parameters required for such critical electronic components. Configuration data is typically stored in a register and static (i.e., it remains unchanged through the lifetime of the product). Thus, the timing vulnerability factor (TVF) is significantly high and it is likely that, at some point over the course of the lifetime of the product, one or more bits of the configuration data will be switched (e.g., due to radiation-induced soft errors). Unfortunately, if even one bit of the configuration data is corrupted, a critical electronic component may malfunction. One technique to minimize any negative impact from configuration data corruption is to periodically refresh all data stored in the register. However, depending upon how often the refresh operation is performed, the corrupt data may cause safety issues. Additionally, such refresh operations may result in a processing delay and an increase in power consumption.

In view of the foregoing, disclosed herein are embodiments of a structure including a register with integrated error detection logic. Specifically, the structure can include a register with an array of flip-flops. Each flip-flop in the array can be associated with one of multiple parity groups such that any two adjacent flip-flops (in any direction) within the array are associated with two different parity groups of the multiple parity groups. This is done to ensure that any flip-flops in the same parity group are physically separated by at least a predetermined minimum separation distance (e.g., which is greater than the radius of a defined bit-flip occurrence region encircling any of a location of a strike by an alpha particle or generation of a secondary ion due to a neutron interaction). In some embodiments, the parity groups can include both even parity groups and odd parity groups. The structure includes integrated error detection logic. This integrated error detection logic can include first logic circuits for the multiple parity groups, respectively. Each first logic circuit for a corresponding parity group can receive data from all flip-flops in the corresponding parity group. The first logic circuit for any even parity group can also receive a previously-stored group-specific even parity bit, whereas the first logic circuit for any odd parity group can receive an inverted version of a previously-stored group-specific odd parity bit. In any case, each first logic circuit for a corresponding parity group can include an XOR tree that processes the received data and parity bit associated with the corresponding parity group to generate and output a group-specific error indicator. The integrated error detection logic can also include a second logic circuit that receives the group-specific error indicators from the first logic circuits and outputs a final error indicator.

By ensuring flip-flops within the same parity group are separated by more than the predetermined minimum separation distance and further by including both even and odd parity groups, the final error indicator can be indicative of any of the following potential errors in the register: an unintended switching of a single stored bit; unintended switching of multiple stored bits; a power supply loss; an unintended reset assertion to switch all stored bits to 1's; an unintended reset assertion to switch all stored bits to 0's; an unintended data shift-operation; and a clock signal fail. The structure can also include a fault management circuit that receives, reads, and, if necessary, acts (e.g., initiates corrective action) in response to the final error indicator. In some embodiments, the fault management circuit can be included on the same chip as the register and integrated error detection logic such that the structure is a system-on-chip (SOC) level arrangement.

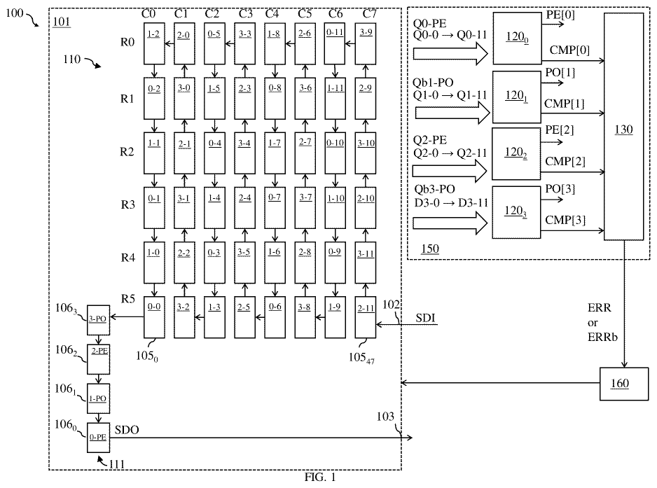

More particularly, FIG. 1 is a schematic diagram illustrating a disclosed embodiment of a structure 100 including a register 101 with integrated error detection logic 150.

Register 101 can include an array 110 of flip-flops, which are arranged in columns and rows. For purposes of illustration, array 110 is shown as having forty-eight flip-flops 105₀-105₄₇ arranged in eight columns (e.g., C0-C7) and six rows (e.g., R0-R5). It should be understood, however, that FIG. 1 is not intended to be limiting and that array 110 could include any suitable number of flip-flops arranged in columns and rows. Each flip-flop 105₀-105₄₇ can be, for example, a D flip-flop with a data input (D), a clock signal input (CLK), a data output (Q), an inverted data output (Qb), and a set and reset options. Those skilled in the art will recognize that a D flip-flop is designed to capture the value of D at a define time in the clock cycle (e.g., the rising edge) and maintain or switch the value of Q to match D. At other times in the clock cycle, Q remains constant. Various different D flip-flop configurations are known in the art and, thus, the details have been omitted from the specification in order to allow the reader to focus on the salient aspects of the disclose embodiments (e.g., related to the register and integrated fault detection logic configurations). In any case, flip-flops 105₀-105₄₇ within array 110 can be series-connected (e.g., Q to D) in a snake-like fashion from one end to the other (e.g., from flip-flop 105₄₇ to flip-flop 105₀), up one column (e.g., C7), over to and down the next column (e.g., C6), over to and up the next column (e.g., C5), and so on, as illustrated.

Additionally, within array 110, each flip-flop 105₀-105₄₇ can be associated with one parity group of multiple parity groups. For purposes of illustration, each flip-flop 105₀-105₄₇ is associated with a given one of four different parity groups: 0, 1, 2, and 3. It should be noted that the number of parity groups can be determined and the association of the different flip-flops in the arrays to the parity groups can be performed so that: (1) any two adjacent flip-flops within the array are associated with two different parity groups of the multiple parity groups (i.e., so that no two adjacent flip-flops in any direction (horizontally, vertically, or diagonally) are associated with the same parity group); and (2) any flip-flops associated with the same parity group are physically separated within the array 110 by at least a predetermined minimum separation distance. For purposes of this disclosure, two “adjacent flip-flops” refers to two flip-flops that are not separated by another flip-flop positioned therebetween in any direction (i.e., in the same row to the right or left, in the same column above or below, or diagonally in an adjacent row and column). Furthermore, the predetermined minimum separation distance between flip-flops in the same parity group can be set so that it greater than the radius of a defined bit-flip occurrence region encircling any alpha particle strike point of impact or the point of generation of a secondary ion due to a neutron interaction. More specifically, when a radiation-induced alpha particle strikes a chip at a particular location (referred to herein as the point of impact or strike location), it may ionize silicon atoms. If the alpha particle strikes a flip-flop within a register, the ionization of silicon atoms at that location may cause the flip-flop to change states (i.e., may cause a soft-error). Furthermore, the ionization of silicon will not be localized to one flip-flop but may spread some known maximum distance in all directions from the point of impact of the alpha particle strike. Thus, any flip-flops adjacent to that point of impact (i.e., within the predetermined maximum distance) are at risk of changing states (i.e., exhibiting soft errors). Similarly, bit flips can occur at the location of generation of a secondary ion due to a neutron interaction. To ensure that no two flip-flops in the same parity group will exhibit soft errors resulting from the same alpha particle strike or secondary ion generation, the predetermined minimum separation distance (dmin-sep) between flip-flops in the same parity group should be greater than the known radius of a defined bit-flip occurrence region that will encircle the point of impact of an alpha particle strike or the point of generation of a secondary ion due to a neutron interaction.

Consider the arrangement of the flip-flops 105₀-105₄₇ associated with the four parity groups: 0, 1, 2, and 3 in the array 110 of FIG. 1.

Each parity group 0, 1, 2, and 3 includes twelve of the forty-eight flip-flops (e.g., see twelve flip-flops in parity group 0, identified as 0-1 to 0-11; see twelve flip-flops in parity group 1, identified as 1-1 to 1-11; see twelve flip-flops in parity group 2, identified as 2-1 to 2-11; and see twelve flip-flops in parity group 3, identified as 3-1 to 3-11). As illustrated, alternating flip-flops in columns C0, C2, C4 and C6 are associated with parity groups 1 and 0 with the bottom flip-flops in C0 and C4 being associated with parity group 0 and the bottom flip-flops in C2 and C6 being associated with parity group 1. Alternating flip-flops in columns C1, C3, C5 and C7 in the array 110 are associated with parity groups 2 and 3 with the bottom flip-flops in C1 and C5 being associated with parity group 3 and the bottom flip-flops in C3 and C7 being associated with parity group 2. As a result, any two adjacent flip-flops within the array are associated with two different parity groups of the multiple parity groups (i.e., so that no two adjacent flip-flops in any direction (horizontally, vertically, or diagonally) are associated with the same parity group). Plus, any flip-flops associated with the same parity group are physically separated within the array 110 by at least a predetermined minimum separation distance.

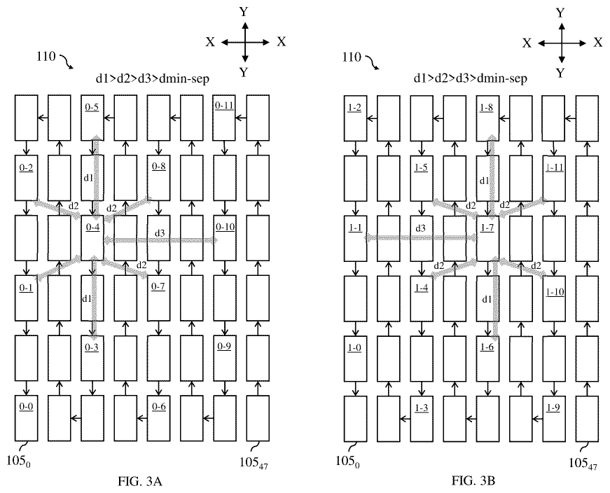

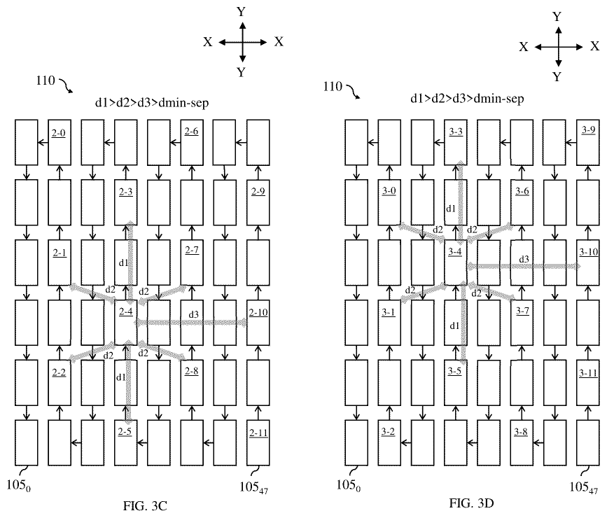

For example, FIG. 3A is a layout diagram highlighting the locations of flip-flops in array 110 associated with parity group 0. FIG. 3B is a layout diagram highlighting the locations of flip-flops in array 110 associated with parity group 1. FIG. 3C is a layout diagram highlighting the locations of flip-flops in array 110 associated with parity group 2. FIG. 3D is a layout diagram highlighting the locations of flip-flops in array 110 associated with parity group 3. With the above-described arrangement, any flip-flop associated with a specific parity group will be separated in the Y direction (up or down) from another flip-flop associated with that same specific parity group by a first distance (d1), will be separated diagonally from another flip-flop associated with that same specific parity group by a second distance (d2), and will be separated in the X direction (right or left) from another flip-flop associated with that same specific parity group by a third distance (d3). It should be understood that the figures are not drawn to scale (e.g., as noted in FIGS. 3A-3D, d3 can be less than d1 and d2).

Technology node-specific design information can indicate, for example: the cell size of a selected flip-flop; design rules for separation between those flip-flops in both the X and Y directions (within the rows and columns, respectively); and the maximum distance between the point of impact of an alpha particle strike on a chip (or the location of generation of a secondary ion due to a neutron interaction) and occurrence of a soft error resulting therefrom. Thus, for example, if the design information for 22 nanometer (nm) fully-depleted silicon-on-insulator (FDSOI) indicates that the maximum distance between the point of impact of an alpha particle strike or the location of generation of a secondary ion due to a neutron interaction and occurrence of a soft error resulting therefrom is 8000 nanometers (nm), then the minimum separation distance (dmin-sep) between flip-flops in the same parity group should be greater than 8000 nm. If the 22 nm FDSOI design information also indicates, d1 is approximately equal to 18,800 nm, d2 is approximately equal to 9200 nm, and d3 is approximately equal to 8300 nm. Thus, as illustrated in each of FIGS. 3A-3D, no two adjacent flip-flops in any direction (horizontally, vertically, or diagonally) are associated with the same parity group and all flip-flops associated with the same parity group are physically separated within the array 110 by greater than dmin-sep (i.e., over 8000 nm).

Optionally, some of the multiple parity groups can be designated to be even parity groups and some can be designated to be odd parity groups. For example, parity groups 0 and 2 can be designated as even parity groups and parity groups 1 and 3 can be designated as odd parity groups, as discussed in greater detail below.

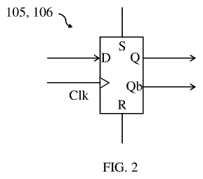

Register 101 can further include an input node 102, an output node 103, and a group 111 of additional flip-flops (one for each parity group) in addition to the array 110. Thus, in a structure 100 with four parity groups, there will be four additional flip-flops (e.g., see additional flip-flops 106₀-106₃ for parity groups 0-3, respectively). Flip-flops 106₀-106₃, like flip-flops 105₀-105₄₇, can be D flip-flops (e.g., as shown in FIG. 2 and described above). Flip-flops 105₄₇ to 105₀ and additional flip-flops 106₃ to 106₀ can be connected in series between input node 102 and output node 103. The additional flip-flops 106₀-106₃ can store group-specific parity bits for the parity groups 0-3, respectively. Those skilled in the art will recognize that a parity bit is added to a set of binary data so that the total number of 1's (including the bit of the parity bit) will be even (for even parity) or odd (for odd parity). Specifically, for even parity, the parity bit is set: (1) at 1 if the set of binary data has an odd number of 1's so that the total number of 1's will be an even number; and (2) at 0 if the set of binary data already has an even number of 1's so that the total number of 1's will remain an even number. For odd parity, the parity bit is set: (1) at 1 if the set of binary data has an even number of 1's so that the total number of 1's will be an odd number; and (2) at 0 if the set of binary data already has an odd number of 1's so that the total number of 1's will remain an odd number.

As mentioned above, register 101 can further have integrated error detection logic 150. The error detection logic 150 can include first logic circuits (one for each parity group). Thus, in a structure 100 with four parity groups, there will be four first logic circuits (e.g., see first logic circuit 120₀-120₃ for parity groups 0-3, respectively). Each first logic circuit 120₀-120₃ for a corresponding parity group 0-3 can be connected to receive the data from the flip-flops in that corresponding parity group. For example, first logic circuit 120₀ can be connected to receive the Q values from all flip-flops associated with parity group 0 (e.g., identified as 0-0 to 0-11). First logic circuit 120₁ can be connected to receive the Q values from all flip-flops associated with parity group 1 (e.g., identified as 1-0 to 1-11). First logic circuit 120₂ can be connected to receive the Q values from all flip-flops associated with parity group 2 (e.g., identified as 2-0 to 2-11). First logic circuit 120₃ can be connected to receive Q values from all flip-flops associated with parity group 3 (e.g., identified as 3-0 to 3-11). The first logic circuits for any even parity group can also be connected to receive a group-specific parity bit stored in a corresponding one of the additional flip-flops. For example, first logic circuits 120₀ and 120₂ for even parity groups 0 and 2 can be connected to receive the Q values from additional flip-flops 106₀ and 106₂, respectively. However, the first logic circuits for any odd parity group can be connected to receive an inverted group-specific parity bit from a corresponding one of the additional flip-flip flops. For example, first logic circuits 120₁ and 120₃ for odd parity groups 1 and 3 can be connected to receive the Qb values from additional flip-flops 106₁ and 106₃, respectively.

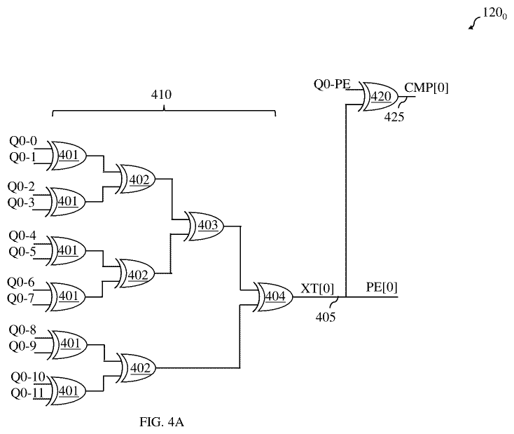

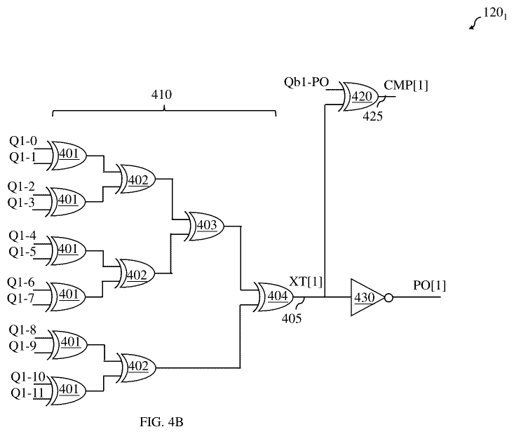

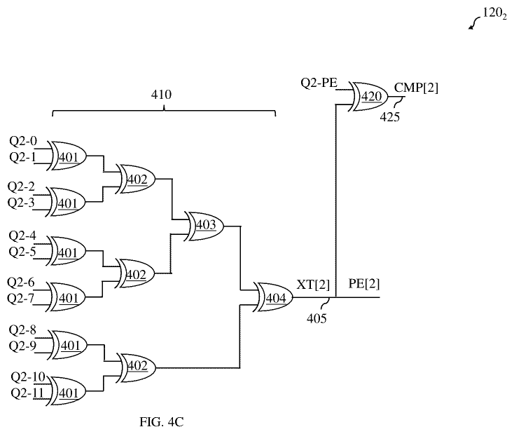

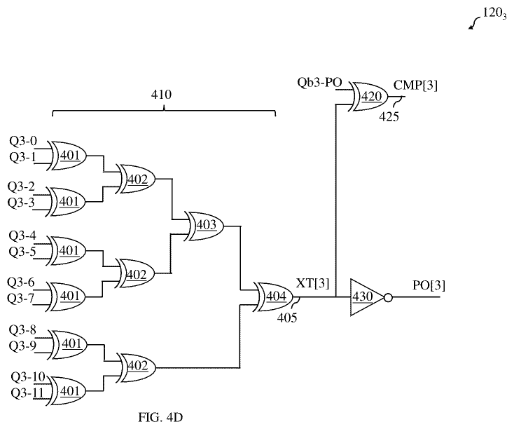

FIGS. 4A-4D are schematic diagrams illustrating first logic circuits 120₀-120₃ for parity groups 0-3 when parity groups 0 and 2 are even parity groups and parity groups 1 and 3 are odd parity groups. Regardless of whether the parity group is even or odd, each of these first logic circuits 120₀-120₃ can include an XOR tree 410. XOR tree 410 can include multiple stages including: a first stage (also referred to as an inputs stage) including XOR gates 401. The number of XOR gates 401 in the input stage can be half the number of Q values received and each XOR gate 401 in the input stage can receive two Q values from two different flip-flops associated within a corresponding parity group such that all Q values from all flip-flops of the corresponding parity group are processed in the first stage. XOR tree 410 can further include one or more downstream stages depending upon the number of XOR gates 401. For example as illustrated, XOR tree includes six XOR gates 401 in the input stage. Thus, it also includes: a second stage with three second XOR gates 402 (each receiving outputs from two of the first XOR gates 401); a third stage with a single third XOR gate 403 receiving outputs from two of the second XOR gates 402; and a fourth stage with a single fourth XOR gate 404 receiving outputs from the third XOR gate 403 and a remaining one of the second XOR gates 402. Each XOR gate 401-404 within XOR tree 410 will output an output logic value based on a comparison of two received input logic values according to a conventional XOR gate truth table. Specifically, the output logic value from any XOR gate 401-404 will be 0 if both input logic values are the same (i.e., both 1's or both 0's) and will be 1 if both input logic values are different (i.e., a 1 and a 0). Thus, the final output logic value (e.g., see XT[0] to XT[3]) at an output node 405 of the XOR tree 410 in any of the first logic circuits 120₀-120₃ will be a 0 if the number of 1's in the received Q values input to the input stage is even and will be 1 if the number of 1's in the received Q values input to the input stage is odd. Configurations for XOR gates are known in the art and, thus, the details thereof have been omitted from this specification in order to allow the reader to focus on the salient aspects of the disclosed embodiments (e.g., related to the register and integrated fault detection logic configurations).

Each first logic circuit 120₀-120₃ can also include an additional XOR gate 420 (a final comparator). The additional XOR gate 420 in each first logic circuit 120₀-120₃ for each parity group 0-3 can be connected to receive, as a first input, the final output logic value XT[0]-XT[3] from the output node 405 of the XOR tree 410 of that first logic circuit 120₀-120₃. A second input to the additional XOR gate will come from an additional flip-flop in the register, as discussed below.

Specifically, for each even parity group, additional XOR gate 420 can also be connected to receive, as a second input, a group-specific parity bit stored in an additional flip-flop for the even parity group within register 101. For example, for even parity group 0, additional XOR gate 420 of first logic circuit 120₀ can receive, as a second input, the Q value (corresponding to the group-specific parity bit) from additional flip-flop 106₀. For even parity group 2, additional XOR gate 420 of first logic circuit 120₂ can receive, as a second input, the Q value (corresponding to the group-specific parity bit) from additional flip-flop 106₂. For each even parity group, additional XOR gate 420 will output a group-specific error indicator (e.g., CMP[0] for even parity group 0 and CMP[2] for even parity group 2) at output node 425. A group-specific error indicator (e.g., CMP[0] and CMP[2]) for an even parity group (e.g., even parity group 0 or even parity group 2) will be: (1) at 0 if both inputs to the additional XOR gate 420 are at 1 or at 0 (thereby indicating that the total number of 1's received as inputs to the first logic circuit is an even number and, thus, no error has been detected in the even parity group); or (2) at 1 if the inputs are different (thereby indicating that the total number of 1's received as inputs to the first logic circuit is an odd number and, thus, an error is detected in the even parity group).

For each odd parity group, additional XOR gate 420 can be connected to receive, as a second input, the inverted group-specific parity bit from an additional flip-flop for that odd parity group within register 101. For example, for odd parity group 1, additional XOR gate 420 of first logic circuit 120₁ can receive, as a second input, the Qb value (corresponding to the inverted group-specific parity bit) from additional flip-flop 106₁. For odd parity group 3, additional XOR gate 420 of first logic circuit 120₃ can receive, as a second input, the Qb value (corresponding to the inverted group-specific parity bit) from additional flip-flop 106₃. For each odd parity group, additional XOR gate 420 will output a group-specific error indicator (e.g., CMP[1] for odd parity group 1 and CMP[3] for odd parity group 3) at output node 425. The group-specific error indicator (e.g., CMP[1] and CMP[3]) for an odd parity group (e.g., odd parity group 1 or odd parity group 3) will be: (1) at 0 if both inputs to the additional XOR gate 420 are at 1 or at 0 (thereby indicating that the total number of 1's received as inputs to the first logic circuit is an odd number and, thus, no error is detected in the odd parity group); or (2) at 1 if the inputs are different (thereby indicating that the total number of 1's received as inputs to the first logic circuit is an even number and, thus, an error has been detected in the odd parity group).

As mentioned above, configurations for XOR gates are known in the art and, thus, the details of additional XOR gates 420 have been omitted from this specification in order to allow the reader to focus on the salient aspects of the disclosed embodiments (e.g., related to the register and integrated fault detection logic configurations).

It should be noted that in each first logic circuit for an even parity group (e.g., see first logic circuit 120₀ for even parity group 0 and first logic circuit 120₂ for even parity group 2), the output logic value on output node 405 (e.g., see XT[0] and XT[1]) is indicative of the even parity pit for the even parity group (e.g., PE[0] and PE[2]). Furthermore, each first logic circuit for an odd parity group (e.g., see first logic circuits 120₁ and 120₃) can further include an inverter 430. Inverter 430 can be connected to the output node 405 of the XOR tree 410 to receive and invert the output logic value such that the output of inverter 430 corresponds to the odd parity pit (e.g., P0[1] and PO[3]) for the odd parity group.

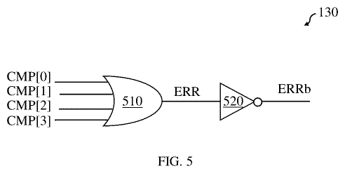

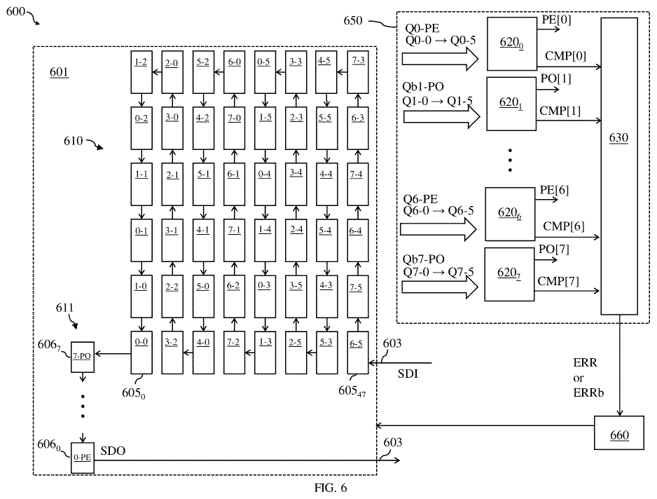

Referring again to FIG. 1, error detection logic 150 can also include a second logic circuit 130, which is connected to receive the group-specific error indicators CMP[0]-CMP[3] from first logic circuits 120₀-120₃ and which is configured to process the group-specific error indicators and output a final error indicator for register 101. FIG. 5 is a schematic diagram illustrating a second logic circuit 130 that could be included in error detection logic 150. As illustrated in FIG. 5, second logic circuit 130 can include a multi-input single-output OR gate 510, which is connected to receive the group-specific error indicators CMP[0]-CMP[3]. Configurations for multi-input single-output OR gates are known in the art and, thus, the details thereof have been omitted from this specification in order to allow the reader to focus on the salient aspects of the disclosed embodiments (e.g., related to the register and integrated fault detection logic configurations). In any case, OR gate 510 can be configured to output an error indicator (ERR), which has a logic value of 0 if all inputs are 0 (thereby indicating that no errors were detected in any of the parity groups 0-3) or a logic value of 1 if any inputs are 1 (thereby indicating that an error was detected in at least one of the parity groups 0-3).

In some embodiments, ERR can be the final error indicator for register 101. Optionally, second logic circuit 130 can further include an inverter 520 connected in series with and downstream of OR gate 510. Configurations for inverters are known in the art and, thus, the details thereof have been omitted from this specification in order to allow the reader to focus on the salient aspects of the disclosed embodiments (e.g., related to the register and integrated fault detection logic configurations). In this case, inverter 520 can receive ERR and can be configured to invert ERR, thereby generating and outputting an inverted error indicator (ERRb). ERRb will have logic value of 1 if ERR is 0 (thereby indicating that no errors were detected in any of the parity groups 0-3) or a logic value of 0 if ERR is 1 (thereby indicating that an error was detected in at least one of the parity groups 0-3). In embodiments, as illustrated, in which second logic circuit 130 includes inverter 520, ERRb can be the final error indicator for register 101.

It should be noted that in a structure 100, as described above, where the flip-flops 105₀-105₄₇ in array 110 are associated with multiple parity groups 0-3, where flip-flops within the same parity group are separated in any direction (vertically, horizontally, or diagonally) by more than the dmin-sep, and where the multiple parity groups include both even and odd parity groups, the final error indicator (e.g., ERR or, alternatively, ERRb as discussed above) can be indicative of any of the following potential errors in register 101 with 100% coverage (i.e., 100% detectability): an unintended switching of a single stored bit, unintended switching of multiple stored bits, a power supply loss, an unintended reset assertion to switch all stored bits to 1's, an unintended reset assertion to switch all stored bits to 0's, an unintended data shift-operation, and a clock signal fail.

Additionally, structure 100 can further include a fault management circuit 160, which is connected to receive the final error indicator (e.g., ERR or ERRb, depending upon the embodiment as discussed above). For purposes of illustration, fault management circuit 160 is discussed below using ERRb as the final error indicator. Fault management circuit 160 can further be configured to read the final error indicator (ERRb) and, if necessary (e.g., if ERRb is at 0 indicating a detected error with array 110 of register 101, as discussed above), to take corrective action in response to the final error indicator (ERRb). Corrective action in response to a final error indicator (ERRb) indicating that an error has been detected within array 110 can include, but is not limited to, initiation of a refresh operation to restore the desired data values stored in the flip-flops 105₀-105_{47.} If the final error indicator (ERRb) continues to indicate an error (e.g., to be at 0) after some predetermined number (e.g., 1 or more) refresh operations have been performed, fault management circuit 160 can issue a system fail notice. Optionally, before reading the final error indicator (ERRb), fault management circuit 160 can attach a sticky bit thereto in order to prevent an override of the final error indicator (ERRb) (e.g., to prevent switching ERRb from 0 to 1). Optionally, fault management circuit 160 can be included on the same chip as register 101 and integrated error detection logic 150 such that structure 100 is a system-on-chip (SOC) level arrangement.

As mentioned above, FIG. 1 is a schematic diagram illustrating an embodiment of a structure 100 including a register 101 with integrated error detection logic 150. In structure 100, each flip-flop 105₀-105₄₇ is associated with a given one of four different parity groups: 0, 1, 2, and 3. However, the number of parity groups illustrated in FIG. 1 and described above is not intended to be limiting. Also disclosed herein are similar structure embodiments where the number of parity groups is greater than four as long as: (1) any two adjacent flip-flops within the array are associated with two different parity groups of the multiple parity groups (i.e., so that no two adjacent flip-flops in any direction (horizontally, vertically, or diagonally) are associated with the same parity group); and (2) any flip-flops associated with the same parity group are physically separated within the array by at least a predetermined minimum separation distance.

For example, FIG. 6 is a schematic diagram illustrating another disclosed embodiment of a structure 600 with a register 601 with integrated error detection logic 650. Structure 600 of FIG. 6 can have essentially the same components as FIG. 1 except as noted below.

Register 601 can include an array 610 of flip-flops, which are arranged in columns and rows. For purposes of illustration, array 610 is shown as having forty-eight flip-flops 605₀-605₄₇ arranged in eight columns (e.g., C0-C7) and six rows (e.g., R0-R5). Flip-flop 605₀-605₄₇ can be, for example, D flip-flops series-connected (e.g., Q to D) in a snake-like fashion from one end to the other (e.g., from flip-flop 605₄₇ to flip-flop 605₀).

Additionally, within array 610, each flip-flop 605₀-605₄₇ can be associated with one parity group of eight parity groups: 0, 1, 2, 3, 4, 5, 6, and 7 and the following conditions apply: (1) any two adjacent flip-flops within the array are associated with two different parity groups of the multiple parity groups (i.e., so that no two adjacent flip-flops in any direction (horizontally, vertically, or diagonally) are associated with the same parity group); and (2) any flip-flops associated with the same parity group are physically separated within the array 610 by at least a predetermined minimum separation distance (dmin_sep). Dmin_sep can be set so that it is greater than the radius of a defined bit-flip occurrence region encircling a location of a strike by an alpha particle or generation of a secondary ion due to a neutron interaction.

Optionally, some of the eight parity groups can be designated to be even parity groups and some can be designated to be odd parity groups. For example, parity groups 0, 2, 4 and 6 can be designated as even parity groups and parity groups 1, 3, 5 and 7 can be designated as odd parity groups, as discussed in greater detail below.

Register 601 can further include an input node 602, an output node 603, and a group 611 of additional flip-flops 606₀-606₇ (one for each parity group) in addition to the array 610. Flip-flops 606₀-606₇, like flip-flops 605₀-605₄₇, can be D flip-flops (e.g., as described above). Flip-flops 605₄₇ to 605₀ and additional flip-flops 606₇ to 606₀ can be connected in series between input node 602 and output node 603. The additional flip-flops 606₀-606₇ can store group-specific parity bits for the parity groups 0-7, respectively. See the detail discussion above with regard to the logic values of stored parity bits for both even and odd parity groups.

Register 601 can further have integrated error detection logic 650. The error detection logic 650 can include first logic circuits (one for each parity group). Thus, in a structure 600 with eight parity groups, there will be eight first logic circuits (e.g., see first logic circuit 620₀-620₇ for parity groups 0-7, respectively) that generate and output eight group-specific error indicators CMP[0]-CMP[7], respectively. First logic circuits 620₀-620₇ for even and odd parity groups can be configured essentially the same as and can function essentially the same as the first logic circuit 120₀-120₃ for even and odd parity groups, as discussed above. However, it should be understood that the XOR tress of first logic circuits 620₀-620₇ will have fewer XOR gates because only half the number of flip-flops (namely six) are associated with each parity group.

Error detection logic 650 can also include a second logic circuit 630, which is connected to receive the group-specific error indicators CMP[0]-CMP[7] from first logic circuits 620₀-620₇ and which is configured to process the group-specific error indicators and output a final error indicator (e.g., ERR or ERRb) for register 601. It should be noted that in a structure 600, as described above, where the flip-flops 605₀-605₄₇ in array 610 are associated with multiple parity groups 0-7, where flip-flops within the same parity group are separated in any direction (vertically, horizontally, or diagonally) by more than the dmin-sep, and where the multiple parity groups include both even and odd parity groups, the final error indicator (e.g., ERR or, alternatively, ERRb) can be indicative of any of the following potential errors in register 601 with 100% coverage (i.e., 100% detectability): an unintended switching of a single stored bit, unintended switching of multiple stored bits, a power supply loss, an unintended reset assertion to switch all stored bits to 1's, an unintended reset assertion to switch all stored bits to 0's, an unintended data shift-operation, and a clock signal fail.

Additionally, structure 600 can further include a fault management circuit 660, which is connected to receive the final error indicator (e.g., ERR or ERRb, depending upon the embodiment as discussed above) and configured in essentially the same manner as fault management circuit 160 of structure 100, discussed above.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a register including an array of flip-flops, wherein each flip-flop in the array is associated with one of multiple parity groups, and wherein any two adjacent flip-flops within the array are associated with two different parity groups of the multiple parity groups; and
first logic circuits for the multiple parity groups, wherein each first logic circuit for a corresponding parity group is connected to receive data from all flip-flops in the corresponding parity group and wherein the first logic circuits output group-specific error indicators for the multiple parity groups.

2. The structure of claim 1, wherein any flip-flops associated with a same parity group are physically separated by at least a predetermined minimum separation distance.

3. The structure of claim 2, wherein the predetermined minimum separation distance is greater than a radius of a defined bit-flip occurrence region encircling a location of a strike by an alpha particle or of generation of a secondary ion due to a neutron interaction.

4. The structure of claim 1, wherein the multiple parity groups include four parity groups.

5. The structure of claim 1, wherein the multiple parity groups include more than four parity groups.

6. The structure of claim 1,
wherein the register further includes additional flip-flops,
wherein the flip-flops of the array and the additional flip-flops are connected in series between an input node and an output node, and
wherein the additional flip-flops store group-specific parity bits for the multiple parity groups, respectively.

7. The structure of claim 1, wherein each first logic circuit includes an XOR tree.

8. The structure of claim 1, further comprising: a second logic circuit including a multi-input single-output OR gate and an inverter connected in series, wherein the multi-input single-output OR gate receives group-specific error indicators from the first logic circuits and the inverter outputs a final error indicator for the register.

9. The structure of claim 8, wherein potential errors indicated by the final error indicator include any of: an unintended switching of a single stored bit, unintended switching of multiple stored bits, a power supply loss, an unintended reset assertion to switch all stored bits to 1's, an unintended reset assertion to switch all stored bits to 0's, an unintended data shift-operation, and a clock signal fail.

10. The structure of claim 8, further comprising a fault management circuit, wherein the fault management circuit receives and reads the final error indicator, takes no action when the final error indicator indicates no detected error in the register, and triggers corrective action when the final error indicator indicates a detected error in the register.

11. The structure of claim 10, wherein the fault management circuit further adds a sticky bit to the final error indicator.

12. A structure comprising:
a register including:
an array of flip-flops, wherein each flip-flop in the array is associated with one of multiple parity groups, wherein the multiple parity groups include even parity groups and odd parity groups and wherein any two adjacent flip-flops within the array are associated with two different parity groups of the multiple parity groups; and
additional flip-flops storing group-specific parity bits for the multiple parity groups; and
first logic circuits for the multiple parity groups,
wherein each first logic circuit for a corresponding even parity group receives data from all flip-flops in the corresponding even parity group and a group-specific even parity bit for the corresponding even parity group,
wherein each first logic circuit for a corresponding odd parity group receives data from all flip-flops in the corresponding odd parity group and an inverted group-specific odd parity bit for the corresponding odd parity group, and
wherein the first logic circuits output group-specific error indicators for the multiple parity groups.

13. The structure of claim 12, wherein the flip-flops of the array and the additional flip-flops are connected in series between an input node and an output node, and wherein any flip-flops associated with a same parity group are physically separated within the array by at least a predetermined minimum separation distance.

14. The structure of claim 13, wherein the predetermined minimum separation distance is greater than a radius of a defined bit-flip occurrence region encircling a location of a strike by an alpha particle or of generation of a secondary ion due to a neutron interaction.

15. The structure of claim 12, wherein the multiple parity groups include four parity groups.

16. The structure of claim 12, wherein the multiple parity groups include more than four parity groups.

17. The structure of claim 12, wherein each first logic circuit includes an XOR tree.

18. The structure of claim 12, further comprising: a second logic circuit including a multi-input single-output OR gate and an inverter connected in series, wherein the multi-input single-output OR gate receives group-specific error indicators from the first logic circuits and the inverter outputs a final error indicator for the register.

19. The structure of claim 18, wherein potential errors indicated by the final error indicator include any of: an unintended switching of a single stored bit, unintended switching of multiple stored bits, a power supply loss, an unintended reset assertion to switch all stored bits to 1's, an unintended reset assertion to switch all stored bits to 0's, an unintended data shift-operation, and a clock signal fail.

20. The structure of claim 18, further comprising a fault management circuit, wherein the fault management circuit receives and reads the final error indicator, adds a sticky bit to the final error indicator, takes no action when the final error indicator indicates no detected error in the register, and triggers corrective action when the final error indicator indicates a detected error in the register.
